(19) United States
(12) Patent Application Publication
(10) Pub. No.: US 2006/0246621 A1
(43) Pub. Date: Nov. 2, 2006

(54) Microelectronic die including thermally conductive structure in a substrate thereof and method of forming same

(75) Inventor: Warren Stuart Crippen, Aloha, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Intel Corporation

(21) Appl. No.: 11/395,109

(22) Filed: Mar. 31, 2006

Related U.S. Application Data
(63) Continuation-in-part of application No. 10/073,859, filed on Feb. 14, 2002, now abandoned.

(51) Int. Cl. H01L 21/00

(52) U.S. Cl. 438/106

(57) ABSTRACT

A microelectronic die and a microelectronic package including the die. The package includes: a substrate; and a microelectronic die bonded to the substrate. The die comprises: a die substrate; a thermally conductive structure extending through the substrate, the thermally conductive structure being configured to conduct heat through a thickness of the substrate and comprising thermal contact zones on the substrate at the backside of the die; a plurality of microelectronic devices on the die substrate; electrical interconnects connecting the microelectronic devices and providing electrical contacts to and from the devices, the interconnects being distinct from the thermally conductive structure. The die further includes a plurality of build-up layers on the die substrate comprising: a plurality of microelectronic devices on the die substrate; and electrical interconnects connecting the microelectronic devices and providing electrical contacts to and from the devices, the interconnects being distinct from the thermally conductive structure.

### CROSS-REFERENCE TO RELATED APPLICATION

This application is a continuation-in-part of currently pending U.S. patent application Ser. No. 10/073,859, filed on Feb. 14, 2002.

### FIELD

Embodiments generally relate to microelectronic dies, and more particularly to heat dissipating structures for such dies.

### BACKGROUND

The computer industry has as one of its goals the continued and increased miniaturization of integrated circuit components. Increased miniaturization among other things means increased density of the integrated circuits, which underscores the importance of providing effective heat dissipation for the circuits.

Heat dissipation from integrated circuits is typically achieved using a thermal interface material such as thermal epoxy or solder to attach a heat spreader to the backside of a die. In the prior art, heat is transferred from a package essentially through the layers making up the die, such as, for example, through one or more layers of silicon and ILD layers, to name just a few. Prior art configurations for heat dissipation have sometimes, however, proven ineffective, especially as die sizes shrink tending to cause impaired die performance among others.

The prior art fails to offer a microelectronic die that allows an effective dissipation of heat from the die while at the same time allowing higher microprocessor speeds and/or further miniaturization of integrated circuits.

### BRIEF DESCRIPTION OF THE DRAWINGS

Embodiments are illustrated by way of example and not limitation in the figures in the accompanying drawings in which like references indicate similar elements, and in which:

FIG. 1 shows a cross-sectional view of a conventional die substrate;

FIG. 2 shows via openings as having been provided in the die substrate of FIG. 1 according to an embodiment;

FIGS. 3a-3c show three respective embodiments of a thermally conductive structure;

FIGS. 4a and 4b show two different die configurations formed from the structure of FIG. 3a according to two respective embodiments;

FIG. 5 shows an intermediate package formed from the die configuration of FIG. 4b;

FIG. 6 shows a microelectronic package formed from the intermediate package of FIG. 5 according to an embodiment; and

FIG. 7 is a schematic representation of a system comprising a microelectronic package such as the microelectronic package of FIG. 6 according to an embodiment.

### DETAILED DESCRIPTION

Embodiments of the present invention contemplate the inclusion of a thermally conductive structure in a die substrate to effect heat dissipation from the inner region of the die through the thermally conductive structure away from the die. The thermally conductive material may comprise any thermally conductive material, such as, for example, copper, a copper alloy, a copper composite, aluminum, an aluminum alloy, or any other conductive material as would be within the knowledge of one skilled in the art. The heat dissipation may, according to an embodiment, take place by way of the thermally conductive material and through thermal contact zones at the backside of the die. The thermal contact zones may be connected to a heat spreader and may correspond to ends of thermal vias. Embodiments of the present invention advantageously allow higher processor speeds by improving heat dissipation from microelectronic packages. By way of example, where copper is used as the thermally conductive material in the inner region of the die, according to an embodiment, there may be approximately a threefold increase in the heat dissipation from the die with respect to similar dies of the prior art.

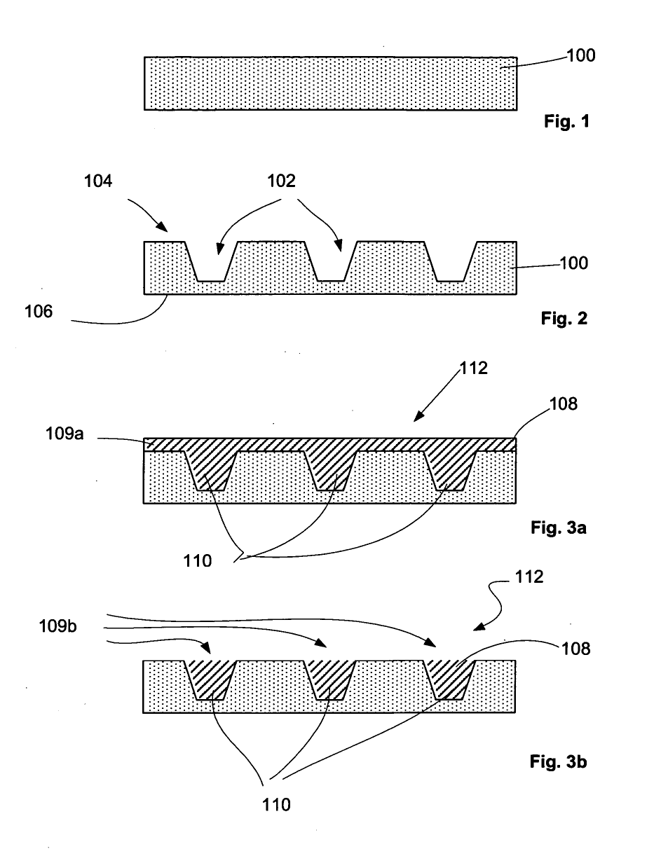

Turning now to the drawings, FIGS. 1-6 depict various exemplary stages of some method embodiments to fabricate a microelectronic package. These stages will be described below.

Referring more particularly to FIG. 1 by way of example, a method according to one embodiment involves providing a die substrate 100, such as a conventional wafer on which dies are typically formed, including, for example, a bare silicon wafer. The die substrate may also include a silicon on insulator substrate, a compound semiconductor substrate and/or other conventional microelectronic substrates. It will be understood that the substrate 100 may include a base substrate and one or more layers on the base substrate.

Referring now to FIG. 2a by way of example, a method embodiment comprises providing via openings, such as via openings 102, on the side of the active surface 104 of the die substrate 100, active surface 104 being disposed opposite the backside 106 of die substrate 100. By “active surface of the die substrate,” what is meant in the context of the instant description is a surface of the die substrate adapted to receive build-up layers thereon to form the die, and disposed opposite the backside of the die substrate adapted to serve as a backside of the die. According to a preferred embodiment, the via openings may be provided by way of laser etching, as would be within the knowledge of one skilled in the art. However, embodiments contemplate the provision of via openings in the die substrate according to any one of the methods available to one skilled in the art. According to one embodiment, as shown in FIG. 2a, the via openings 102 may be blind openings, that is, may be openings closed off at one end thereof. However, according to an alternative embodiment, via openings may be provided in the die substrate 100 which openings may extend through a thickness of the die substrate.

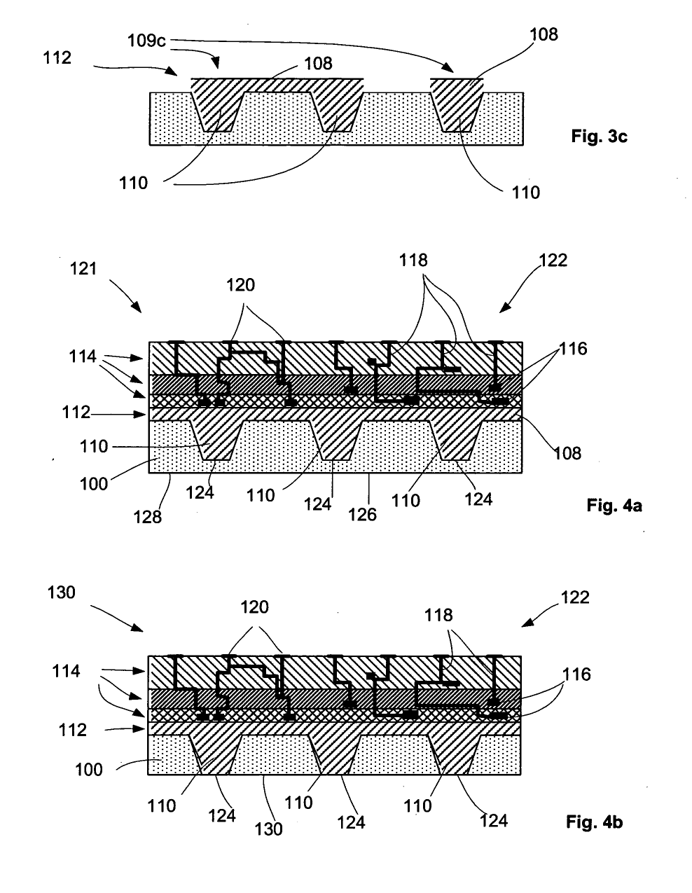

Referring now to FIG. 3a-3c by way of example, a method embodiment comprises providing a thermally conductive material 108 on the active surface 104 of the die substrate 100 to fill the via openings 102. The thermally conductive material 108 may include any thermally conductive material, such as, for example, copper, a copper alloy, a copper composite, aluminum, or an aluminum alloy. As seen in FIG. 3a, the thermally conductive material 108 may be provided in the form of a thermally conductive layer 109a as shown. To achieve a smooth upper surface of layer 109a in FIG. 3a, after provision of the material 108, the thus deposited material may, according to an embodiment, be planarized according to well known methods, such as, for example, by way of chemical mechanical polishing. The thermally conductive material 108 may further be selectively deposited according to a predetermined pattern in a well known manner, such as through selective seeding, as shown by way of example in FIGS. 3b and 3c to form discrete thermally conductive regions 109b and 109c, respectively, of the thermally conductive structure. A pattern of discrete thermally conductive regions may be predetermined based for example on heat dissipation needs from the die or on real estate needs on the die substrate. In the alternative, however, FIGS. 3b and 3c could be deemed to show results of further processing of the thermally conductive layer 109a of FIG. 3a to provide the discrete regions 109b and 109c, as will be explained in the paragraph that follows.

The thermally conductive material 108 may in any event be provided in a conventional manner, such as, for example, by way of electroless plating, electrolytic plating, chemical vapor deposition, physical vapor deposition, sputtering, evaporation, or other well known methods. An adhesion promoter (now shown), such as, for example silicon dioxide or trichlorosilane, may optionally be provided onto the active surface 104 of die substrate 100 prior to provision of the thermally conductive material 108 in order to enhance an adhesion of the thermally conductive material 108 to the substrate active surface 104. Optionally, tantalum may be provided onto silicon dioxide in a well known manner to enhance its adhesion promoting qualities. The deposition of the adhesion promoter may be achieved according to known methods as readily recognizable by one skilled in the art. The layer of adhesion promoter may be deposited using vapor deposition. Many other alternatives are also possible according to embodiments of the present invention The thickness of the layer of thermally conductive material may be optimized for thermal transfer. According to a preferred embodiment of the present invention, where copper is used as the layer of thermally conductive material, the copper layer may have a thickness of between about 25 Angstroms to about 1 micron. Provision of the thermally conductive material 108 yields thermal vias 110 which are adapted to enhance a conduction of heat from active devices on the die toward a heat spreader, as will be explained in greater detail further below.

Referring back now to FIGS. 3b and 3c, optionally, according to some embodiments, the thermally conductive layer 109a may be further patterned to yield discrete thermally conductive regions, such as regions 109b of FIGS. 3b and 109c of FIG. 3c. A patterning of the thermally conductive layer 109a may be effected for example to make more room for microelectronic devices or build-up layers of the die to be provided on the die substrate, and further as a function of die hot spots. Patterning of layer 109a may take place according to any one of well known techniques, such as, for example, by reactive ion etching, sputter etching, other etching, and/or chemical mechanical polishing (for example in the case of the configuration of FIG. 3b).

Referring back now to FIGS. 3a-3c by way of example, a thermally conductive structure 112 according to the shown embodiment would include, in the case of FIG. 3a, layer 109a. In the case of FIG. 3b, the thermally conductive structure 112 would include the totality of discrete regions 109b, and, in FIG. 3c, it would include the totality of discrete regions 109c. Although FIGS. 4a, 4b, 6 and 7 depict the die configuration of FIG. 3a as being further processed for inclusion into an exemplary microelectronic package, it is to be understood that embodiments comprise within their scope the inclusion of any die configuration, such as the configurations of FIG. 3b or 3c, into a microelectronic package, as long as the die includes a thermally conductive structure that conducts heat through a thickness of the die substrate.

Referring next to FIG. 4a by way of example, a method embodiment includes providing a plurality of build-up layers 114 on the active surface 104 of substrate 100. In the shown embodiment, three build-up layer 114 are shown, although it is understood that embodiments are of course not so limited. By “build-up” layer, what is meant in the context of embodiments is a layer (possibly including a plurality of sublayers) including at least one of: microelectronic devices, such as microelectronic devices 116 of FIG. 4a, an interlayer dielectric material, an insulating layer comprising, for example, silicon dioxide or silicon nitride, electrical interconnects such as electrical interconnects 118 of FIG. 4a, including, for example, signal lines, to name just a few. The “build-up layer” is thus used herein to designate any layer that may be built up onto a die substrate to make up a part of a microelectronic die. The microelectronic devices 116 may include active and/or passive devices such as transistors, diodes, resistors, capacitors and/or other devices. Microelectronic devices 116 may also include optoelectronic and/or micro-electromechanical devices. The provision of build-up layers is well known to those having skill in the art. Thus, the provision of build-up layers may take place according to a predetermined configuration and function as envisioned for a given die to be built up onto the die substrate 100. As seen in FIG. 4a, the build-up layers may include a plurality of microelectronic devices 116, and electrical interconnects 118 connecting the microelectronic devices 116 and providing contacts 120, shown in FIG. 4a in the form of bumping sites on the active surface of the die. The bumping sites provide sites for a bonding of the die to a substrate, such as to a substrate or a printed circuit board, in a known manner, such as through solder reflow possibly followed by the provision of an underfill material. Contacts 120 according to embodiments may thus provide electrical connection to and from the devices 116 from regions exterior to the die. As suggested in FIG. 4a, the thermally conductive structure 112 is, according to embodiments, distinct from the electrical interconnects 118, in the sense that the thermally conductive structure is not disposed to conduct electricity to or from any of the microelectronic devices.

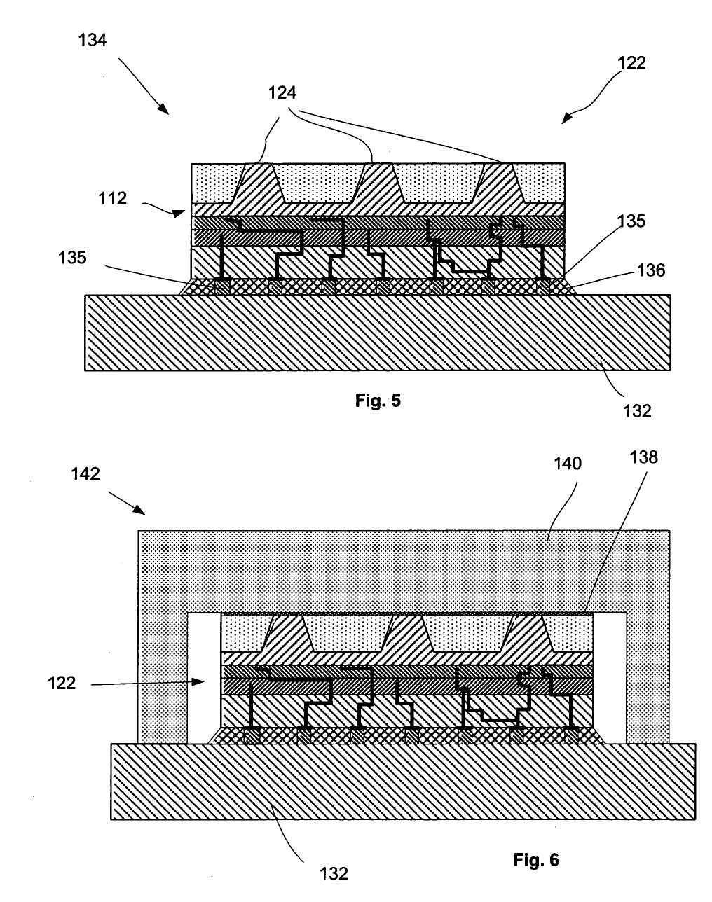

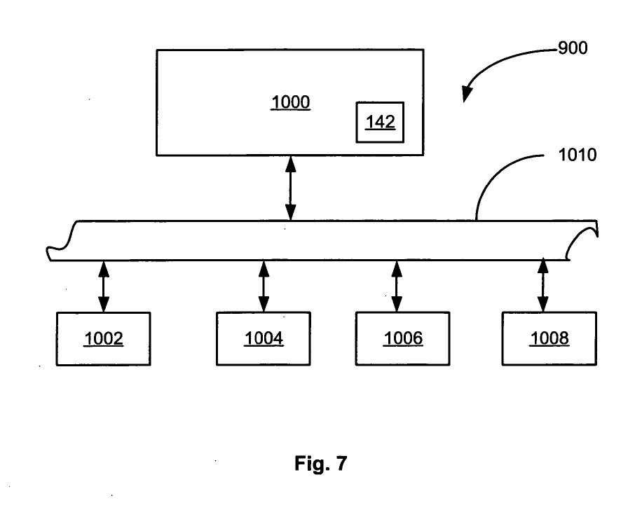

According to one embodiment, the configuration 121 shown in FIG. 4a may represent a die 122, where the thermally conductive structure 112 includes thermal contact zones 124 adapted to dissipate heat from a backside 126 of the die 122 corresponding to a backside 128 of die substrate 100, the thermal vias 110 in FIG. 4a being blind thermal vias. Optionally, referring now to FIG. 4b, a preferred method embodiment includes removing a portion of the backside 128 of die substrate 100 to expose thermal contact zones 124 at a newly defined backside 130 of die substrate 100, thus converting the blind thermal vias 110 of FIG. 4a into through thermal vias 110 of FIG. 4b, such that the thermal contact zones are defined at a newly defined backside 130 of die substrate 100. A removal of the backside 128 of die substrate 100 may be effected according to any one of well known methods, such as, for example, through conventional atmospheric downstream plasma etching technology. Thus, the configuration 130 of FIG. 4b represents a die 122 according to a preferred embodiment, where the thermal vias 110 are through vias. Although FIGS. 5 and 6 to be described below show a further processing of the die 122 of FIG. 4b, other die configurations, such as those of FIGS. 4a and 4c, for example, may further be placed in a package according to the method embodiment described in FIGS. 5 and 6, or according to other method embodiments of the present invention.

A configuration of thermally conductive structure according to embodiments, such as structure 112 of FIG. 4a or 4b, including but not limited to a size, a distribution and a configuration of thermal vias provided in the die substrate, may preferably be dictated by hot spots predicted for the particular die that includes the thermally conductive structure. In general, according to a preferred embodiment, a high density of relatively large vias may be provided onto the substrate in order to maximize heat transfer from the die during its operation. For example, more vias could be provided in regions where hot spots on the die are anticipated. An exemplary range of vias per surface area that would qualify as high density in the context of embodiments of the present invention is dependent among other things on the size of the vias. Large vias may be used according to an embodiments that will have a pitch that is relatively large but that will allow a large area to be covered by the thermal contact zones formed in these vias. See thermal contact zones 28 in FIG. 6. The pitch of the vias is defined as the distance between the respective centerlines of adjacent vias. Thus, “high density” in the context of embodiments of the present invention is a function of the size of the thermal contact zones formed in the vias and of the pitch of the vias for a given area. By way of example, for a thermal contact zone diameter of about 100 microns and a via pitch of about 150 microns, a density of about 49 thermal contact zones per millimeters squared would qualify as high density according to embodiments of the present invention. Another example would be a density of about 16 thermal contact zones per millimeters squared for a thermal contact zone diameter of about 200 microns and a via pitch of about 250 microns. The thermal contact zone diameters noted above are large compared to standard contact pad sizes (corresponding for example to sizes of contacts 120 in FIG. 4a or 4b) that are typically in the order of about 25 microns or less. The above two densities are merely examples of likely configurations according to embodiments of the present invention, and are not meant to be exhaustive of the possibilities thereof. A given density may for example be chosen according to embodiments the present invention as a function of die size and optimized to provide the most stable wafer condition that would maximize the surface area of the thermal contact zones on the backside of the die.

Referring now to FIGS. 5 and 6, stages of packaging a die, such as die 122 of FIG. 4b, are shown up to an attachment of a heat spreader according to an embodiment. In particular, referring to FIG. 5, die 122 may be bonded to a substrate 132, such as, for example, to a substrate of a printed circuit board, in a conventional manner to provide an intermediate die package 134. A bonding of die 122 to substrate 132 may include the provision of solder joints 135 to electrically bond the contacts 120 of die 122 to corresponding pads (not shown) on substrate 132, such as through a conventional solder reflow technique. Optionally, as seen in FIG. 5, an underfill material 136 may be provided between the die 122 and substrate 132, such as, for example, by way of a capillary underflow regime, or by way of a no-flow underfill regime, as would be within the knowledge of the skilled person. As further seen in FIG. 5, the thermal contact zones 124 on the backside 130 of die substrate 100, corresponding to a backside of die 122, are shown as remaining exposed.

Referring thereafter to FIG. 6 by way of example, a method embodiment may include the attachment of a heat spreader, such as, for example, heat spreader 138, to the intermediate package 134 of FIG. 5 in a conventional manner, for example by way of a thermal interface material 140, such as solder, which may contact the thermal contact zones 124 of thermally conductive structure 112. By way of example, the thermal interface material 140 may be placed over the thermal contact zones 124 as a paste, ribbon or plug, as readily recognizable by one skilled in the art. Attachment of heat spreader 138 to intermediate package 134 would then yield microelectronic package 142 as shown in FIG. 6. The attachment of the heat spreader may be effected through a conventional reflowing process where the thermal interface material provides a direct connection between the thermal connection zones and the heat spreader.

As best seen in FIG. 6, a microelectronic package formed according to method embodiments may allow for improved heat dissipation from a die. Such improvement may be provided by the provision of a thermally conductive structure within the die to conduct heat away from the die from regions very close to the die's circuitry.

Advantageously, method embodiments allow for improved thermal conduction from an inner region of the die away from the die, such as to a heat spreader, increasing the ability of the heat spreader to remove and dissipate heat from the die. Embodiments of the present invention are applicable to all microelectronic devices requiring heat dissipation.

Referring to FIG. 7, there is illustrated one of many possible systems 900 in which embodiments of the present invention may be used. In one embodiment, the electronic assembly 1000 may include a microelectronic package, such as package 142 of FIG. 6. Assembly 1000 may further include a microprocessor. In an alternate embodiment, the electronic assembly 1000 may include an application specific IC (ASIC). Integrated circuits found in chipsets (e.g., graphics, sound, and control chipsets) may also be packaged in accordance with embodiments of this invention.

For the embodiment depicted by FIG. 7, the system 900 may also include a main memory 1002, a graphics processor 1004, a mass storage device 1006, and/or an input/output module 1008 coupled to each other by way of a bus 1010, as shown. Examples of the memory 1002 include but are not limited to static random access memory (SRAM) and dynamic random access memory (DRAM). Examples of the mass storage device 1006 include but are not limited to a hard disk drive, a compact disk drive (CD), a digital versatile disk drive (DVD), and so forth. Examples of the input/output module 1008 include but are not limited to a keyboard, cursor control arrangements, a display, a network interface, and so forth. Examples of the bus 1010 include but are not limited to a peripheral control interface (PCI) bus, and Industry Standard Architecture (ISA) bus, and so forth. In various embodiments, the system 90 may be a wireless mobile phone, a personal digital assistant, a pocket PC, a tablet PC, a notebook PC, a desktop computer, a set-top box, a media-center PC, a DVD player, and a server.

The invention has been described with reference to specific exemplary embodiments thereof. It will, however, be evident to persons having the benefit of this disclosure, that various modifications and changes may be made to these embodiments without departing from the broader spirit and scope of the invention. The specification and drawings are, accordingly, to be regarded in an illustrative rather than in a restrictive sense.

What is claimed is:

1. A method of forming a microelectronic die having a backside and an active surface, the method, comprising:
providing a die substrate;
providing a thermally conductive structure configured to conduct heat through a thickness of the die substrate, the thermally conductive structure comprising thermal contact zones disposed to dissipate heat from a backside of the die;
providing a plurality of build-up layers on the die substrate to form the die comprising:
providing a plurality of microelectronic devices on the die substrate; and
providing electrical interconnects connecting the microelectronic devices and providing electrical contacts to and from the devices, the interconnects being distinct from the thermally conductive structure.

2. The method of claim 1, wherein providing a thermally conductive structure comprises:
providing a plurality of via openings in an active surface of the substrate;
providing a thermally conductive material in the via openings to create corresponding thermal vias in the substrate, the thermally conductive structure including the thermal vias, each thermal via defining a thermal contact zone at an end thereof at a backside of the substrate.

3. The method of claim 2, wherein:
providing a plurality of via openings comprises providing a plurality of blind via openings;
providing a thermally conductive material comprises:
filling the blind via openings with the thermally conductive material; and
removing a portion of the substrate to expose the thermal contact zones to convert the blind vias into the thermally conductive vias.

4. The method of claim 2, wherein providing via openings comprises using a laser beam to etch the via openings in the substrate.

5. The method of claim 3, wherein removing a portion comprises etching a portion of the substrate to expose the thermal contact zones and to define the backside of the substrate.

6. The method of claim 1, wherein the build up layers comprise at least one signal layer.

7. The method of claim 1, wherein the thermally conductive structure comprises one of copper, a copper alloy, a copper laminate, a copper composite, aluminum and an aluminum alloy.

8. The method of claim 1, wherein providing a thermally conductive material comprises metallizing the active surface of the substrate after providing the via openings.

9. The method of claim 8, wherein metallizing comprises at least one of electroless plating, electrolytic plating, sputtering, evaporation and chemical vapor deposition.

10. The method of claim 1, wherein the thermally conductive structure includes a plurality of discrete thermally conductive regions.

11. The method of claim 1, wherein providing the thermally conductive structure comprises configuring the thermally conductive structure as a function of die hot spots.

12. The method of claim 11, wherein providing the thermally conductive structure comprises configuring the structure such that the thermal contact zones are distributed on the backside of the die as a function of die hot spots.

13. The method of claim 1, wherein providing the thermally conductive structure comprises configuring the structure such that the thermal contact zones have a diameter between about 100 microns and about 200 microns.

14. The method of claim 1, wherein providing the thermally conductive structure comprises configuring the structure such that the thermal contact zones are distributed at a density of between about 16 thermal contact zones and about 49 thermal contact zones per mm².

15. A microelectronic die comprising:
a die substrate;
a thermally conductive structure extending through the substrate, the thermally conductive structure being configured to conduct heat through a thickness of the substrate and comprising thermal contact zones on the substrate at the backside of the die;
a plurality of build-up layers on the die substrate comprising:
a plurality of microelectronic devices on the die substrate; and
electrical interconnects connecting the microelectronic devices and providing electrical contacts to and from the devices, the interconnects being distinct from the thermally conductive structure.

16. The die of claim 15, wherein the thermally conductive structure comprises a plurality of thermal vias extending through the thickness of the substrate.

17. The die of claim 15, wherein the thermally conductive structure comprises at least one of copper, a copper alloy, a copper laminate, a copper composite, aluminum and an aluminum alloy.

18. The die of claim 15, wherein the thermally conductive structure includes a plurality of discrete thermally conductive regions.

19. The die of claim 15, wherein the thermally conductive structure is configured as a function of die hot spots.

20. The die of claim 19, wherein the thermally conductive structure is configured such that the thermal contact zones are distributed on the backside of the die as a function of die hot spots.

21. The die of claim 15, wherein the thermally conductive structure is configured such that the thermal contact zones have a diameter between about 100 microns and about 200 microns.

22. The die of claim 15, wherein the thermally conductive structure is configured such that the thermal contact zones are distributed at a density of between about 16 thermal contact zones and about 49 thermal contact zones per mm².

23. A microelectronic package comprising:
a substrate;
a microelectronic die bonded to the substrate, the die comprising:
a die substrate;
a thermally conductive structure extending through the substrate, the thermally conductive structure being configured to conduct heat through a thickness of the substrate and comprising thermal contact zones on the substrate at the backside of the die;
a plurality of build-up layers on the die substrate comprising:
a plurality of microelectronic devices on the die substrate; and
electrical interconnects connecting the microelectronic devices and providing electrical contacts to and from the devices, the interconnects being distinct from the thermally conductive structure; and
a heat spreader thermally coupled to the thermal contact zones of the thermally conductive structure.

24. The package of claim 23, wherein the thermally conductive structure comprises a plurality of thermal vias extending through the thickness of the substrate.

25. The package of claim 23, wherein the thermally conductive structure comprises at least one of copper, a copper alloy, a copper laminate, a copper composite, aluminum and an aluminum alloy.

26. The package of claim 23, wherein the thermally conductive structure is configured such that the thermal contact zones are distributed on the backside of the die as a function of die hot spots.

27. The package of claim 23, wherein the thermally conductive structure is configured such that the thermal contact zones have a diameter between about 100 microns and about 200 microns.

28. The package of claim 23, wherein the thermally conductive structure is configured such that the thermal contact zones are distributed at a density of between about 16 thermal contact zones and about 49 thermal contact zones per mm².

29. A system comprising:
a microelectronic assembly including:
a microelectronic package comprising:
a substrate;
a microelectronic die bonded to the substrate, the die comprising:
a die substrate;
a thermally conductive structure extending through the substrate, the thermally conductive structure being configured to conduct heat through a thickness of the substrate and comprising thermal contact zones on the substrate at the backside of the die;
a plurality of build-up layers on the die substrate comprising:
a plurality of microelectronic devices on the die substrate; and
electrical interconnects connecting the microelectronic devices and providing electrical contacts to and from the devices, the interconnects being distinct from the thermally conductive structure; and
a heat spreader thermally coupled to the thermal contact zones of the thermally conductive structure; and
a main memory coupled to the assembly.

30. The system of claim 29, wherein the thermally conductive structure comprises a plurality of thermal vias extending through the thickness of the substrate.
